(19) United States
(12) Patent Application Publication
(10) Pub. No.: US 2026/0353702 A1
(43) Pub. Date: Nov. 5, 2026

(54) ACCUMULATION-BASED TRANSISTOR

(71) Applicant: SEMICONDUCTOR COMPONENTS INDUSTRIES, LLC, Scottsdale, AZ (US)

(72) Inventor: Peter MOENS, Erwetegem (BE)

(73) Assignee: SEMICONDUCTOR COMPONENTS INDUSTRIES, LLC, Scottsdale, AZ (US)

(21) Appl. No.: 19/551,959

(22) Filed: Feb. 27, 2026

Related U.S. Application Data
(60) Provisional application No. 63/799,130, filed on May 2, 2025.

(51) Int. Cl. H10D 30/63; H10D 30/01; H10D 62/00; H10D 62/10; H10D 64/01; H10D 64/66

(52) U.S. Cl. CPC H10D 30/635; H10D 30/025; H10D 62/054; H10D 62/111; H10D 64/01306; H10D 64/661

(57) ABSTRACT

A transistor is disclosed. The transistor includes an epitaxial region having a first conductivity type, a source region having the first conductivity type and disposed in the epitaxial region at an upper surface of the epitaxial region, and a channel region having the first conductivity type and disposed along the upper surface of the epitaxial region and adjacent to the source region. The transistor further includes a shield region having a second conductivity type and disposed to surround a bottom side and opposing lateral sides of the channel region along at least a portion of a length of the channel region, a drift region formed by a lower portion of the epitaxial region and forming a contiguous path of the first conductivity type with the channel region via a JFET region extending through the shield region.

This application claims the benefit of U.S. Provisional Patent Application No. 63/799,130, filed May 2, 2025, which is hereby incorporated by reference herein in its entirety.

### TECHNICAL FIELD

The disclosure relates generally to semiconductor devices, and particularly to accumulation-based metal-oxide semiconductor field-effect transistors (MOSFETs).

### BACKGROUND

Power electronics may be used to control the conversion and distribution of electric power. For example, switching power converters may be used to create a direct current (DC) voltage from an alternating current (AC) voltage by switching current through a magnetic element such as an inductor. Conversely, inverters can be used to convert a DC voltage to an AC voltage. In these and other forms of power electronics, power switches may be used to control the conversion and flow of power through the power-conversion system and to the electronic circuitry to be powered by the device.

Power transistors utilized in such power-conversion systems may be required to handle high currents and to withstand large voltages. The inventor of embodiments of the present disclosure has recognized that optimizing certain performance parameters of power transistors may come at the expense of worsening other parameters. For example, the inventor of embodiments of the present disclosure has recognized that certain techniques utilized to optimize the on-state resistance (RON) of a power transistor, such as the use of a trench gate, may come at the cost of higher gate leakage and lower reliability. Embodiments of the present disclosure may address one or more of these challenges.

### SUMMARY

The examples herein enable techniques for manufacturing an accumulation-based transistor with low on-state resistance (RON) and a high breakdown voltage (BV).

According to one example, a transistor includes an epitaxial region having a first conductivity type, a source region having the first conductivity type and disposed in the epitaxial region at an upper surface of the epitaxial region, a channel region having the first conductivity type and disposed along the upper surface of the epitaxial region and adjacent to the source region, a shield region having a second conductivity type and disposed to surround a bottom side and opposing lateral sides of the channel region along at least a portion of a length of the channel region, and a drift region formed by a lower portion of the epitaxial region and forming a contiguous path of the first conductivity type with the channel region via a JFET region extending through the shield region. In some embodiments, the shield region includes a lateral-shield region and disposed in the epitaxial region adjacent to the channel region along a length of the channel region, and a buried-shield region and disposed in the epitaxial region under at least a portion of the channel region. In the same or different embodiments, the lateral-shield region and the buried-shield region form a contiguous area of the second conductivity type. In the same or different embodiments, the transistor further includes a pillar region having the second conductivity type extending vertically below at least a portion of the buried-shield region. In the same or different embodiments, the lateral-shield region, the buried-shield region, and the pillar region form a contiguous area of the second conductivity type. In the same or different embodiments, the pillar region and the drift region collectively form a super-junction. In the same or different embodiments, alternating areas of the pillar region and the drift region extend in a direction that is orthogonal to a length direction of the channel region. In the same or different embodiments, the shield region further includes an end-shield region having the second conductivity type and disposed at the upper surface of the epitaxial region and at a second end of the channel region that is opposite to a first end of the channel region adjacent to the source region. In the same or different embodiments, the lateral-shield region, the buried-shield region, and the end-shield region form a contiguous area of the second conductivity type. In the same or different embodiments, the transistor further comprises a gate structure having a gate dielectric disposed above the channel region, and a polysilicon gate disposed above the gate dielectric, wherein the polysilicon gate is doped to have the second conductivity type. In the same or different embodiments, the transistor further comprises a gate structure having a gate oxide disposed above the channel region, and a polysilicon gate disposed above the gate oxide, wherein the polysilicon gate is doped to have the first conductivity type. In the same or different embodiments, the gate structure extends above an entirety of the channel region and above an entirety of the JFET region. In the same or different embodiments, the first conductivity type is n-type, and the second conductivity type is p-type.

According to another example, an accumulation-based transistor includes an epitaxial region having a first conductivity type, a source region having the first conductivity type and disposed in the epitaxial region at an upper surface of the epitaxial region, a channel region having the first conductivity type and disposed along the upper surface of the epitaxial region and adjacent to the source region, a lateral-shield region having a second conductivity type and disposed in the epitaxial region adjacent to the channel region along a length of the channel region, a buried-shield region having the second conductivity type and disposed in the epitaxial region under at least a portion of the channel region, and a drift region formed by a lower portion of the epitaxial region extending deeper than the buried-shield region, the drift region forming a contiguous path of the first conductivity type with the channel region via a JFET region located laterally to the buried-shield region. In some embodiments, the accumulation-based transistor further includes a pillar region having the second conductivity type extending vertically below at least a portion of the buried-shield region, wherein the pillar region and the drift region extend in a direction that is orthogonal to a length direction of the channel region and collectively form a super-junction.

Another example includes a method for manufacturing an accumulation-based transistor, the method including forming an epitaxial region having a first conductivity type on a substrate, forming a buried-shield region having a second conductivity type beneath a portion of a channel region that is adjacent to an upper surface of the epitaxial region, forming a continuous path of the first conductivity type from the channel region to a drift region in a lower portion of the epitaxial region via a JFET region that has the first conductivity type and extends vertically through the buried-shied region, forming a lateral-shield region having the second conductivity type in the epitaxial region adjacent to the channel region along a length of the channel region, forming a gate structure above the channel region, and forming a source region having the first conductivity type adjacent to an end of the channel region. In some embodiments, forming the gate structure includes forming a gate dielectric above the channel region and depositing, above the gate dielectric, a polysilicon gate that is doped to have the second conductivity type. In some embodiments, the method further includes implanting a pillar region having the second conductivity type in a lower portion of the epitaxial region to form a super-junction in the lower portion of the epitaxial region at a depth beyond the buried-shield region. In the same or different embodiments, the lateral-shield region, the buried-shield region, and the pillar region form a contiguous area of the second conductivity type. In the same or different embodiments, the method further includes forming an end-shield region having the second conductivity type at a second end of the channel region that is opposite to a first end of the channel region adjacent to the source region. In the same or different embodiments, the lateral-shield region, the buried-shield region, and the end-shield region form a contiguous area of the second conductivity type.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1A illustrates a perspective cross-sectional view of a transistor in accordance with embodiments of the present disclosure.

FIG. 1B illustrates a cross-sectional view of a transistor in accordance with embodiments of the present disclosure.

FIG. 1C illustrates a cross-sectional view of a transistor in accordance with embodiments of the present disclosure.

FIG. 1D illustrates a cross-sectional view of a transistor in accordance with embodiments of the present disclosure.

FIG. 2A illustrates a perspective cross-sectional view of a transistor in accordance with embodiments of the present disclosure.

FIG. 2B illustrates a perspective cross-sectional view of a transistor in accordance with embodiments of the present disclosure.

FIG. 2C illustrates a perspective cross-sectional view of a transistor in accordance with embodiments of the present disclosure.

FIGS. 3A-3C illustrate perspective cross-sectional views of various examples of transistors in accordance with embodiments of the present disclosure.

FIGS. 4A-4C illustrate side cross-sectional views of various examples of transistors in accordance with embodiments of the present disclosure.

FIG. 5 illustrates a perspective cross-sectional view of a transistor in accordance with embodiments of the present disclosure.

FIG. 6A illustrates a perspective cross-sectional view of a transistor in accordance with embodiments of the present disclosure.

FIG. 6B illustrates a perspective cross-sectional view of a transistor in accordance with embodiments of the present disclosure.

FIG. 6C illustrates a perspective cross-sectional view of a transistor in accordance with embodiments of the present disclosure.

FIG. 7 illustrates a method for manufacturing an accumulation-based transistor in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other elements and connections.

Further, although the terms “first,” “second,” “third,” and so forth may be used herein to describe various elements, these elements should not be limited by these terms. Terms such as “first,” “second,” and “third” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element.

Embodiments disclosed herein may include a transistor. The transistor may be a metal-oxide semiconductor field-effect transistor (MOSFET). In some embodiments, the transistor may be a silicon carbide transistor formed on a silicon carbide substrate. In other embodiments, the transistor may be implemented in silicon, gallium nitride, or any other suitable semiconductor material. As described in further detail below, the transistor may include a super-junction, and may thus also be referred to as a super-junction transistor.

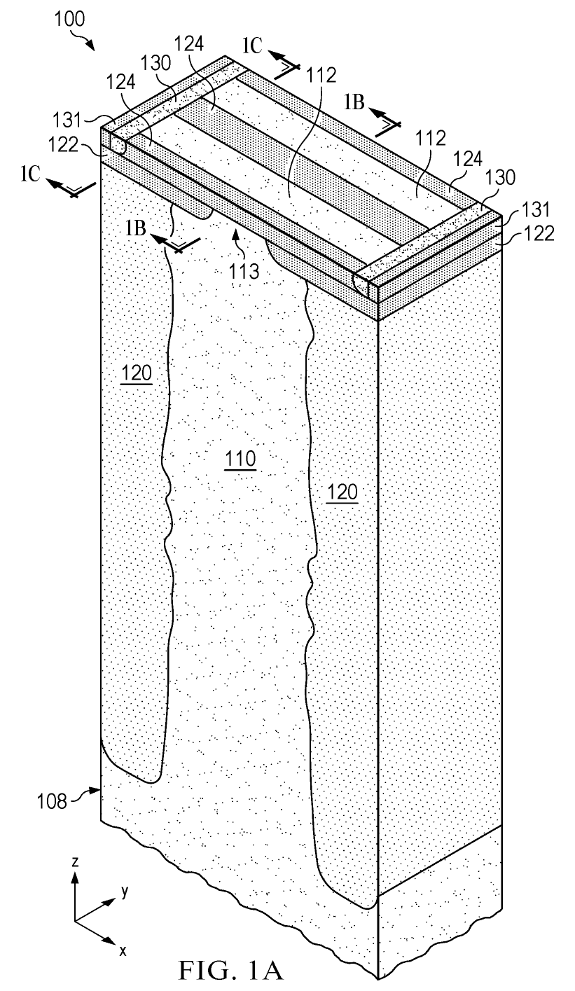

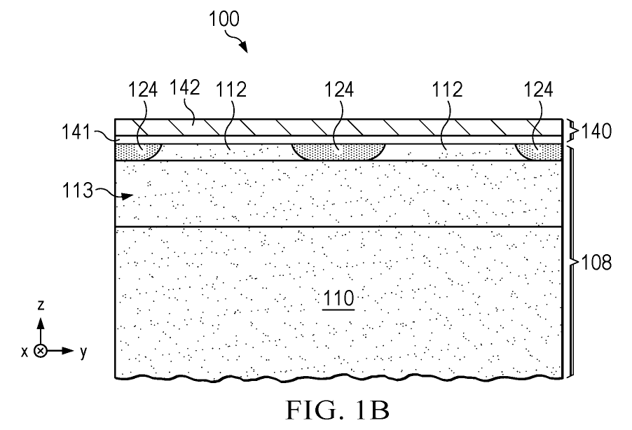

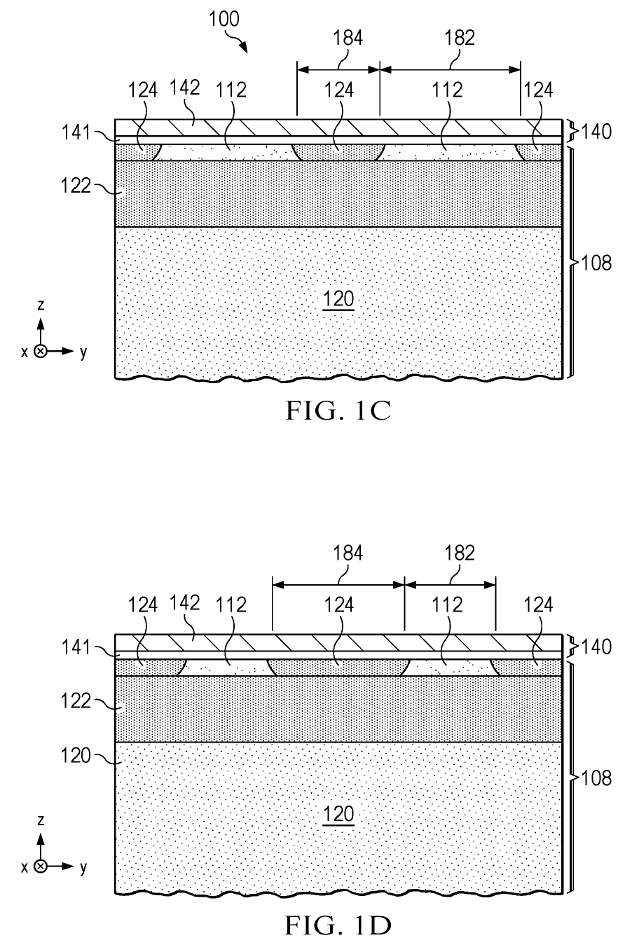

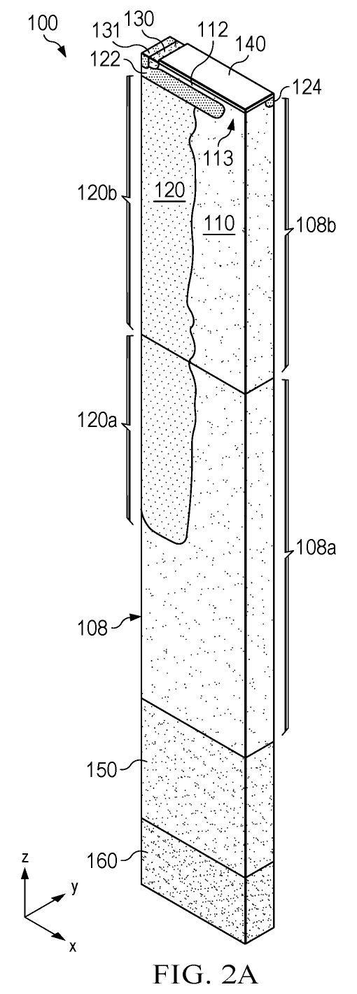

FIG. 1A illustrates a perspective cross-sectional view of transistor 100 in accordance with embodiments of the present disclosure. Specifically, FIG. 1A illustrates a perspective cross-sectional view of a portion of transistor 100 cut out from a semiconductor substrate. Although FIG. 1A illustrates multiple fingers of transistor 100, transistor 100 may include further fingers (for example, 10, 100, 1000, or more) repeated in a similar pattern in further portions of the semiconductor substrate not shown in FIG. 1A. In some embodiments, transistor 100 may be a silicon carbide transistor formed on a silicon carbide (SiC) substrate. In other embodiments, transistor 100 may be implemented in silicon (Si), gallium nitride (GaN), or any other suitable semiconductor material. As described in further detail below, transistor 100 may include an accumulation-based channel region, and may thus also be referred to as an accumulation-based transistor. As also described in further detail below, transistor 100 may include a super-junction, and may thus also be referred to as a super-junction transistor.

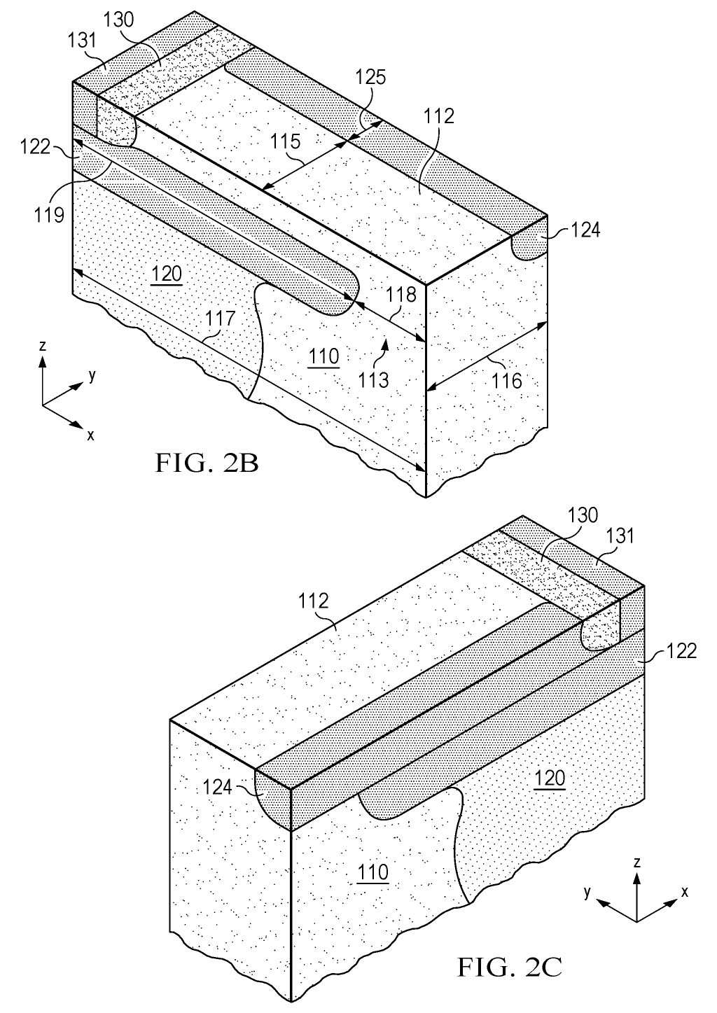

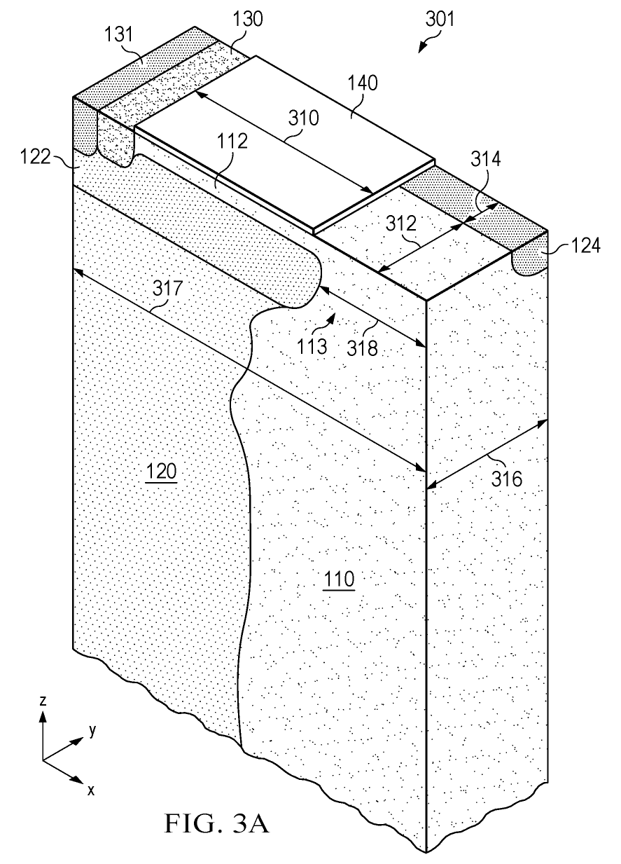

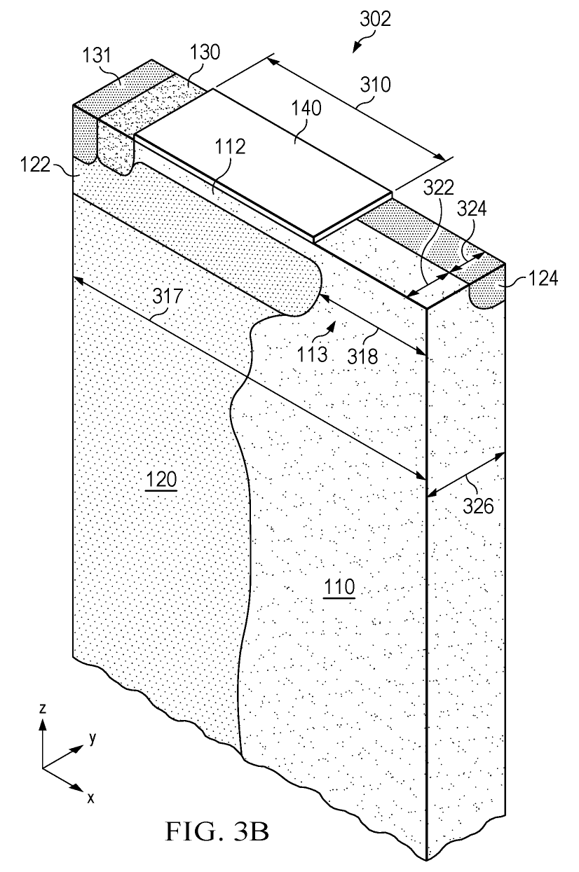

Various elements of transistor 100 may be formed in or disposed above epitaxial region 108. As described in further detail below with reference to FIG. 2A, epitaxial region 108 may be epitaxially grown on a substrate 160 that may form the drain of transistor 100. For example, epitaxial region 108 may be a silicon carbide epitaxial region formed by an epitaxial growth using a silicon carbide substrate as the seed for the epitaxial growth. Epitaxial region 108 may be initially formed with a first conductivity type. For example, in embodiments where transistor 100 is an n-type transistor (“NMOS” or “NMOS transistor”), epitaxial region 108 may be initially formed with an n-type doping that may be included, for example, during the epitaxial growth. And as described directly below with reference to FIG. 1A, various elements of transistor 100 may be formed in epitaxial region 108 by further doping patterns applied to epitaxial region 108 after the epitaxial growth.

As shown in FIG. 1A, transistor 100 may include drift region 110, channel region 112, JFET region 113, pillar region 120, a shield region (including buried-shield region 122 and lateral-shield region 124), source region 130, and shield-contact region 131. Although omitted from FIG. 1A in order to show the top-view layout of channel region 112 and lateral-shield region 124, transistor 100 may also include a gate structure 140 as shown in FIGS. 1B and 1C for example.

Transistor 100 may be an accumulation-based transistor. For example, channel region 112 may have the same first conductivity type (for example, n-type) as source region 130, JFET region 113, drift region 110, and substrate 160. A gate structure 140 may be disposed above channel region 112 on the upper surface of epitaxial region 108. Further, a shield region of the second conductivity type (for example, p-type) may surround the bottom side and the lateral sides of channel region 112 along at least a portion of the length of channel region 112. For example, a shield region of the second conductivity type may surround the bottom side and the lateral sides of the channel region 112 along at least a majority portion of the length of channel region 112. A shield-contact region 131 may be coupled to the same source contacts that may couple source region 130 to upper metal layers that couple to a source terminal of transistor 100. Accordingly, the shield region (including buried-shield region 122 and lateral-shield region 124) may be held at the same voltage potential as source region 130 during operation of transistor 100. The built-in potential of the p-n junction between the shield region and the channel region 112 may pinch off the conduction path of channel region 112 when the gate-to-source voltage (Vgs) of transistor 100 is held at zero. Transistor 100 may thus be referred to as an enhancement-mode device or a normally-off device that is in an off-state when the gate-to-source voltage is held at zero. When a positive voltage above a gate-to-source threshold of transistor 100 is applied, the gate charge may attract further majority carriers to channel region 112, thereby opening the conduction path for majority carriers through channel region 112. Transistor 100 may thus conduct current from substrate 160 (which may form the drain of transistor 100), through drift region 110 and JFET region 113, through channel region 112, and to source region 130 (which may form the source of transistor 100).

Because transistor 100 is an accumulation-based device that utilizes majority carriers through channel region 112, transistor 100 may have a lower channel resistance than conventional power transistors that utilize inversion in a channel region to open a flow of minority carries through that channel region. Further, because channel region 112 and gate structure 140 of transistor 100 are disposed in a lateral fashion relative to the upper surface of epitaxial region 108, transistor 100 may achieve a lower on-state resistance without the drawbacks of trench-gate designs that have vertically disposed gates and channels (such as reliability and gate leakage). The layout of the different regions of transistor 100, which support the aforementioned operation and benefits, are described in further detail below.

Source region 130 may be disposed in epitaxial region 108 adjacent to an upper surface of epitaxial region 108. Source region 130 may have the first conductivity type. For example, in embodiments where transistor 100 is NMOS transistor, source region 130 may be formed with an n-type doping. In some embodiments, source region 130 may have a heavier n-type doping concentration than the initial n-type doping of epitaxial region 108.

Channel region 112 may be disposed along the upper surface of epitaxial region 108 and adjacent to source region 130. Channel region 112 may have the first conductivity type. For example, in embodiments where transistor 100 is an NMOS transistor, channel region 112 may have an n-type doping. Channel region 112 may be formed along the upper surface of epitaxial region 108 and may have borders defined in part by the patterning of a shield region (for example, a p-type shield region) that may partially surround channel region 112. Channel region 112 may have a depth of approximately 75 nm, for example, and an n-type doping concentration of approximately 1e17 cm⁻³, for example.

In some embodiments, channel region 112 may be formed by the upper portions of epitaxial region 108 at the upper surface of epitaxial region 108 that remain after various shield regions are implanted. In such embodiments, channel region 112 may have the same n-type doping concentration as the initial n-type doping of epitaxial region 108. In other embodiments, additional doping may be implanted in channel region 112 to vary the n-type doping concentration of channel region 112 relative to the initial n-type doping of epitaxial region 108. For example, epitaxial region 108 may in some embodiments be formed with an initial n-type doping concentration of 1e16 cm⁻³, and additional doping may be added to channel region 112 to increase the n-type doping concentration of channel region 112 to 8e16 cm⁻³.

Various other elements of transistor 100 are described below with reference to a location relative to the length and/or ends of channel region 112. For the purposes of the present disclosure, the length of channel region 112 may refer to the dimension of the longer edges of a rectangular shape, for example, of channel region 112 on the x-y plane shown in FIG. 1A. Further, for the purposes of the present disclosure, the lateral sides of channel region 112 may refer to the longer edges of the rectangular shape of channel region 112 while the ends of channel region 112 may refer to the shorter edges of the rectangular shape of channel region 112 on the x-y plane in FIG. 1A.

As shown in FIG. 1A, transistor 100 may include a shield region, including buried-shield region 122 and lateral-shield region 124, that may have a second conductivity type opposite of the first conductivity type. For example, in embodiments where transistor 100 is an NMOS transistor, the shield region (including buried-shield region 122 and lateral-shield region 124) may be formed with a p-type doping. In some embodiments, the p-type doping may be implanted after epitaxial region 108 is initially formed with an epitaxial growth. For example, a p-type doping may be implemented with aluminum (Al) to form buried-shield region 122 and lateral-shield region 124.

The various areas of the shield region (including buried-shield region 122 and lateral-shield region 124) may be disposed to surround a bottom side and opposing lateral sides of channel region 112 along at least a portion of a length of channel region 112. For example, buried-shield region 122 may be disposed in the epitaxial region 108 under at least a portion of channel region 112. Further, instances of lateral-shield region 124 may be disposed in the epitaxial region 108 at the upper surface of epitaxial region 108 and adjacent to channel region 112 along a length of channel region 112. For example, as shown in FIG. 1A, instances of lateral-shield region 124 may be disposed in the direction of the x-axis on opposing lateral sides of channel region 112. Buried-shield region 122 and lateral-shield region 124 may thus surround the bottom side and the lateral sides of the channel region 112 along at least a majority portion (greater than half, for example) of the length of channel region 112.

Drift region 110 may have the first conductivity type. For example, in embodiments where transistor 100 is NMOS transistor, drift region 110 may have an n-type doping. Drift region 110 may be formed by a lower portion of epitaxial region 108. In some embodiments, drift region 110 may be formed by remaining areas of epitaxial region 108 that are not otherwise occupied by source region 130, channel region 112, lateral-shield region 124, buried-shield region 122, and as described below, pillar region 120. In such embodiments, drift region 110 may have the same n-type doping concentration as the initial n-type doping of epitaxial region 108. Drift region 110 may form a contiguous path of the first conductivity type with channel region 112 via a JFET region 113 that extends through the shield region (for example, that extends vertically through portions of buried-shield region 122). The contiguous path of the first conductivity type with channel region 112, JFET region 113, and drift region 110 is further illustrated in FIG. 1B.

FIG. 1B illustrates a cross-sectional view of transistor 100 in accordance with embodiments of the present disclosure. Specifically, FIG. 1B illustrates a cross-section view of transistor 100 along the y-z plane at the cut-line 1B shown in FIG. 1A.

As shown in FIG. 1B, transistor 100 may include a gate structure 140 disposed above channel region 112 and lateral-shield region 124. Gate structure 140 may include gate dielectric 141 disposed above channel region 112 (and also above lateral-shield region 124 in some embodiments). Gate dielectric 141 may be formed with a thin layer of silicon dioxide, for example, or any suitable dielectric layer including, for example, silicon nitride (Si₃N₄), hafnium oxide (HfO₂), aluminum oxide (Al₂O₃), and/or aluminum nitride (AlN). In some embodiments, the gate dielectric 141 may have a thickness less than a depth of channel region 112. For example, channel region 112 may have a depth from the upper surface of epitaxial region 108 of approximately 75 nm. In such embodiments, the gate dielectric 141 may have a thickness of, for example, 40 nm, 30 nm, 20 nm, or less. The low thickness of gate dielectric 141 may provide for improved control of the gate charge and may thus allow for a lower maximum gate-drive voltage (for example, 12 volts) for transistor 100. Such a lower maximum gate-drive voltage (for example, 12 volts) may allow for further improvements of related gate drivers that may only need to output a maximum gate drive voltage of 12 volts as opposed to the higher gate drive voltages of 18 volts or more that are common with power transistors.

Gate structure 140 may also include polysilicon gate 142 disposed above gate dielectric 141. In some embodiments, polysilicon gate 142 may be doped to have the second conductivity type. For example, in embodiments where transistor 100 is an NMOS transistor, polysilicon gate 142 may have a p-type doping. A p-type doping for polysilicon gate 142 may help increase the gate-to-source threshold voltage V_{TH} at which transistor 100 turns on, thus helping to make transistor 100 an enhancement mode device that is normally-off with a gate-to-source voltage of zero. In other embodiments, polysilicon gate 142 may be doped to have the first conductivity type. For example, in embodiments where transistor 100 is an NMOS transistor, polysilicon gate 142 may have an n-type doping.

As shown in FIG. 1B, channel region 112 may have approximately the same depth (for example, approximately 75 nm) relative to the upper surface of epitaxial region 108 as lateral-shield region 124. JFET region 113 may extend vertically from channel region 112 to drift region 110. Accordingly, channel region 112, JFET region 113, and drift region 110, may collectively form a contiguous path of the first conductivity type. For the purposes of the present disclosure, JFET region 113 may be considered to be an upper portion of drift region 110 that extends through the depth of buried-shield region 122 as shown in FIG. 1A. For example, JFET region 113 may represent an upper portion of drift region 110 that is located between the lateral ends of two instances of buried-shield region 122. Thus, as shown in the cross-section view of FIG. 1B, JFET region 113 may extend vertically from channel region 112 to the lower portions of drift region 110 that are at a depth beneath the depth of buried-shield region 122. To be clear, JFET region 113 does not represent a junction-field-effect-transistor (JFET) device separate from transistor 100, but instead represents an area within transistor 100 with a JFET-like configuration where an n-type conduction path extends through opposing p-type regions.

FIG. 1C illustrates a cross-sectional view of transistor 100 in accordance with embodiments of the present disclosure. Specifically, FIG. 1C illustrates a cross-section view of transistor 100 along the y-z plane at the cut-line 1C shown in FIG. 1A.

As collectively shown in FIGS. 1A and 1C, the various areas of the shield region (including buried-shield region 122 and lateral-shield region 124) may be disposed to surround a bottom side and opposing lateral sides of channel region 112 along at least a portion of a length of channel region 112. Buried-shield region 122 may be disposed in the epitaxial region 108 under at least a portion of channel region 112 (including the portion of channel region 112 shown in the cross-section view of FIG. 1C). Further, instances of lateral-shield region 124 may be disposed in the epitaxial region 108 at the upper surface of epitaxial region 108 and adjacent to channel region 112 along a length of channel region 112. For example, as collectively shown in FIGS. 1A and 1C, instances of lateral-shield region 124 may be disposed in the direction of the x-axis on opposing lateral sides of channel region 112. In some embodiments, lateral-shield region 124 may have the same or greater depth than channel region 112 and may thus abut buried-shield region 122. Accordingly, lateral-shield region 124 and buried-shield region 122 may form a contiguous area of the second conductivity type (for example, a contiguous area with p-type doping).

As collectively shown in FIGS. 1A and 1C, pillar region 120 may abut a lower edge of buried-shield region 122 and may extend vertically below at least a portion of buried-shield region 122. Pillar region 120 may have the same second conductivity type as buried-shield region 122 and lateral-shield region 124. Accordingly, lateral-shield region 124, buried-shield region 122, and pillar region 120 may form a contiguous area of the second conductivity type. In embodiments where transistor 100 is an NMOS transistor, pillar region 120 may be formed with a p-type doping. In some embodiments, the p-type doping may be implanted after epitaxial region 108 is formed with an epitaxial growth.

Referring back to FIG. 1A, pillar region 120 and drift region 110 may form an area with alternating columns of the first conductivity type (for example, the n-type doping of drift region 110) and the second conductivity type (for example, the p-type doping of pillar region 120). Pillar region 120 and drift region 110 may collectively form a super-junction. And for the purposes of the present disclosure, the area with alternating columns of pillar region 120 and drift region 110 may be referred to as a super-junction area. Such a super-junction area may improve the breakdown voltage (BV) of transistor 100. For example, the alternating columns of pillar region 120 and drift region 110 may be doped at respective concentrations such that the overall super-junction area is charge balanced. The charge balance of pillar region 120 and drift region 110 may provide for an even spread of the electric fields that may be induced when high voltages across the drain to source of transistor 100 are incurred in operation. Accordingly, the super-junction area may provide for a higher blocking voltage, and therefore a higher breakdown voltage (BV), as compared to a fully n-type drift layer.

The alternating columns of pillar region 120 and drift region 110 may also help reduce the on-state resistance of transistor 100. For example, an increased p-type doping concentration for pillar region 120 may allow for an increase in the n-type doping concentration for drift region 110, while still maintaining the charge balance of the super-junction area to support the breakdown voltage (BV). In turn, the higher n-type doping of drift region 110 may also reduce the contribution of drift region 110 to the overall on-state resistance (RON) of the conduction path from source region 130, through channel region 112 and JFET region 113, and through drift region 110 toward the drain of transistor 100.

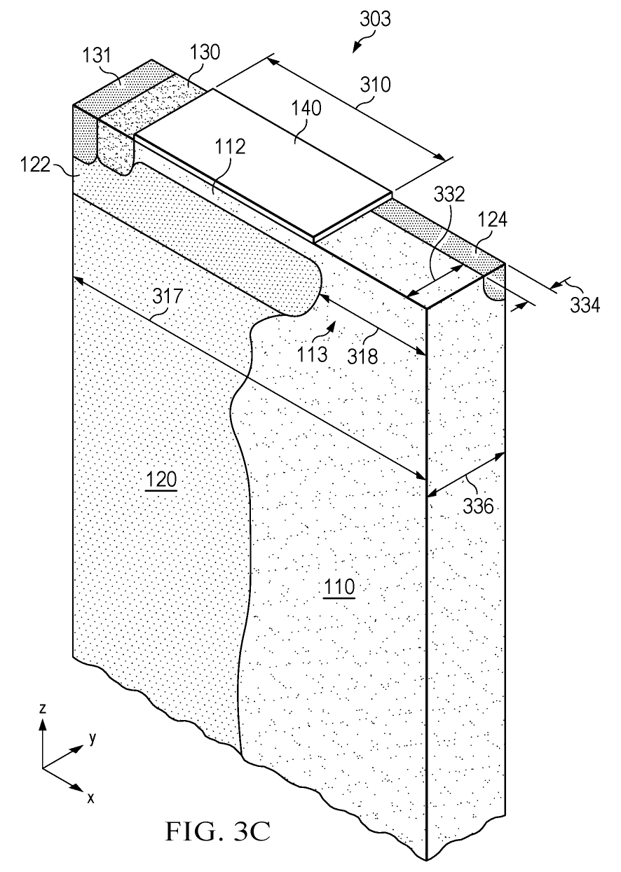

In some embodiments, the alternating areas of pillar region 120 and drift region 110 may extend in a direction that is orthogonal to a length direction of channel region 112. For example, as shown in FIG. 1A, the alternating areas of pillar region 120 and drift region 110 may have a length that extends in the direction of the y-axis, which may be orthogonal to the length of channel region 112 that extends in the direction of x-axis. By patterning pillar region 120 and drift region 110 to extend in a direction orthogonal to the direction of the length of channel region 112, the widths and pitch of pillar region 120 and drift region 110 may be determined separately from the pitch of the various fingers of the channel region 112 (and lateral-shield region 124). The widths and pitch of the alternating areas of pillar region 120 and drift region 110 may therefore be selected based on target on-resistance (RON) and breakdown voltage (BV) values, without being limited to the same widths and pitch of alternating fingers of channel region 112 and lateral-shield region 124. As described below with reference to FIGS. 1C-1D and also FIGS. 3A-3C, the widths and pitch of alternating fingers of channel region 112 and lateral-shield region 124 may be designed based on desired short-circuit withstand time (SCWT), on-state resistance (RON), and maximum gate oxide electric field (E_{OX_MAX}).

FIG. 1D illustrates a cross-sectional view of a transistor in accordance with embodiments of the present disclosure. FIG. 1D illustrates a cross-sectional view of an alternative embodiment of transistor 100 with different proportions for the respective widths of channel region 112 and lateral-shield region 124 relative to those shown in FIG. 1C.

In some embodiments, such as shown in FIG. 1C, the channel-region width 182 of channel region 112 may be greater than the lateral-shield width 184 of lateral-shield region 124. In other embodiments, such as shown in FIG. 1D, the channel-region width 182 of channel region 112 may be less than the lateral-shield width 184 of lateral-shield region 124. In yet further embodiments, the channel-region width 182 of channel region 112 may be approximately equal to the lateral-shield width 184 of lateral-shield region 124 (notwithstanding some variation due to semiconductor process variation).

In some embodiments, repeated instances of channel region 112 and lateral-shield region 124 may have a lateral pitch of 0.8 µm, with a channel-region width 182 of 0.6 µm and a lateral-shield width 184 of 0.2 µm, for example. In other embodiments, repeated instances of channel region 112 and lateral-shield region 124 may have a lateral pitch of 0.8 µm, with a channel-region width 182 of 0.4 µm and a lateral-shield width 184 of 0.4 µm, for example. In yet further embodiments, repeated instances of channel region 112 and lateral-shield region 124 may have a lateral pitch of 0.8 µm, with a channel-region width 182 less than 0.4 µm lateral-shield width 184 greater than 0.4 µm.

The relative widths of channel region 112 and lateral-shield region 124 may be designed based on desired short-circuit withstand time (SCWT), on-state resistance (RON), and maximum gate oxide electric field (E_{OX_MAX}) values. For example, a greater channel-region width and a smaller lateral-shield width relative to the collective pitch of channel region 112 and lateral-shield region 124 may provide for a greater channel area for a given amount of semiconductor chip space, and thus a smaller RON for a given amount of semiconductor chip space. Conversely, a smaller channel-region width and a greater lateral-shield width relative to the collective pitch of channel region 112 and lateral-shield region 124 may provide for (i) a lower saturation current under short-circuit conditions, thereby providing for a greater SCWT, and (ii) greater electric field protection thereby permitting thinner gate dielectrics with a lower E_{OX_MAX} rating (and greater charge control as described above). As described in further detail below with reference to FIGS. 3A-3C, the pitch of repeated instances of channel region 112 and lateral-shield region 124 may be greater than or less than 0.8 µm, and different proportions for the channel-region width 182 relative to the lateral-shield width 184 may be selected based on desired gate-to-drain capacitance (Cgd) and gate-to-source capacitance (Cgs) values.

FIG. 2A illustrates a perspective cross-sectional view of transistor 100 in accordance with embodiments of the present disclosure. Specifically, FIG. 2A illustrates a zoomed out perspective cross-sectional view of a cell of transistor 100 that is repeated eight times, for example, in FIG. 1A. As shown in FIG. 2A, transistor 100 may include substrate 160, buffer region 150, various features disposed in epitaxial region 108 as described above with reference to FIGS. 1A-1D, and also gate structure 140. In some embodiments, gate structure 140 may extend above an entirety of the channel region 112 and above an entirety of the JFET region 113.

In some embodiments, substrate 160 may be 100 µm thick for example. Substrate 160 may serve as the drain of transistor 100, and further back-side metal processing on the lower surface of substrate 160 may couple substrate 160 to the drain terminal of transistor 100. Substrate 160 may be heavily doped relative to the doping of epitaxial region 108. For example, substrate 160 may have an n-type doping concentration implemented with nitrogen at 5e18 cm⁻³ while epitaxial region 108 may have an initial n-type doping concentration implemented with nitrogen at 1e16 cm⁻³.

As described above, epitaxial region 108 may be formed with an epitaxial growth using substrate 160 as the seed. In some embodiments, transistor 100 may optionally further include a buffer region 150 between substrate 160 and epitaxial region 108. The buffer region 150 may have the same first conductivity type as substrate 160 and epitaxial region 108 with a doping concentration greater than the doping concentration of epitaxial region 108 and lower than the doping concentration of substrate 160. For example, in embodiments as described above where substrate 160 may has an n-type doping concentration implemented with nitrogen at 5e18 cm⁻³, and epitaxial region 108 has an initial n-type doping concentration implemented with nitrogen at 1e16 cm⁻³, buffer region 150 may have an n-type doping concentration implemented with nitrogen at 1e17 cm⁻³. The medium doping concentration of buffer region 150 may help ensure that the electric field that is spread across the depth of drift region 110 does not reach the heavily doped substrate 160. In some embodiments, buffer region 150 may be considered a higher-doped portion of epitaxial region 108, and may be formed with the same epitaxial growth as epitaxial region 108 but with a higher-concentration doping.

As shown in FIG. 2A, epitaxial region 108 may be formed by the combination of first epitaxial growth 108a and second epitaxial growth 108b. In some embodiments, the depth of pillar region 120 may be limited by the achievable depth of semiconductor process doping-implant tools. Thus, in some embodiments, multiple epitaxial growth processes may be used to form epitaxial region 108. A first growth process may be used to form first epitaxial growth 108a having a depth of 5.0 µm for example. The first pillar-region portion 120a may then be implanted in the first epitaxial growth 108a. After first pillar-region portion 120a is implanted, a second growth process may be used to form second epitaxial growth 108b having a depth of 3.0 µm for example. The second pillar-region portion 120b may then be implanted in the second epitaxial growth 108b. As described above with reference to FIG. 1A, further elements of transistor 100 such as source region 130, channel region 112, JFET region 113, shield-contact region 131, buried-shield region 122, and lateral-shield region 124, may also be formed at or near the upper surface of epitaxial region 108 (for example, the upper surface of second epitaxial growth 108b) by further doping implants.

FIGS. 2B and 2C illustrate perspective cross-sectional views of transistor 100 in accordance with embodiments of the present disclosure. Specifically, FIGS. 2B and 2C illustrate from different sides the upper portions of the same cell of transistor 100 that is shown in FIG. 2A. Gate structure 140 is omitted from FIGS. 2B and 2C to allow view of underlying elements.

As shown in FIG. 2B, the cell may have a cell length 117 that equals a buried-shield length 119 plus a JFET-area length 118. For example, in some embodiments, each cell of transistor 100 may have a cell length 117 equal to 1.6 µm with a buried-shield length 119 of 1.2 µm and a JFET-area length 118 of 0.4 µm. Further the cell may have a cell width 116 that is equal to channel width 115 plus shield width 125. In some embodiments, the cell width 116 may be for example 0.4 µm with a channel width 115 of 0.3 µm and a shield width 125 of 0.1 µm (corresponding to example embodiments described above with reference to FIGS. 1B and 1C with a channel-region width 182 of 0.6 µm and a lateral-shield width 184 of 0.2 µm when viewing multiple cells mirrored in the direction of the x-axis and in the direction of the y-axis).

As shown in FIG. 2C, buried-shield region 122 may abut lateral-shield region 124 and may extend downward from lateral-shield region 124. Further, pillar region 120 may abut buried-shield region 122 and may extend downward from buried-shield region 122. Accordingly, lateral-shield region 124, buried-shield region 122, and pillar region 120 may form a contiguous area of the second conductivity type (for example, formed with p-type doping in embodiments where transistor 100 is an NMOS transistor). Although not shown in FIGS. 2B and 2C, shield-contact region 131 may be coupled the same source contacts that may couple source region 130 to upper metal layers that couple to a source terminal of transistor 100. Accordingly, shield-contact region 131, lateral-shield region 124, buried-shield region 122, and pillar region 120 may be held at the same voltage potential as source region 130 during operation of transistor 100.

FIGS. 3A-3C illustrate perspective cross-sectional views of various examples of transistors in accordance with embodiments of the present disclosure. Specifically, FIGS. 3A-3C each illustrate a zoomed out perspective cross-sectional view of a cell of a transistor that may serve as an embodiment of the cell of transistor 100 shown in FIGS. 2A-2C for example.

Transistors 301, 302, 303 shown in FIGS. 3A-3C may include drift region 110, channel region 112, JFET region 113, pillar region 120, buried-shield region 122, lateral-shield region 124, source region 130, shield-contact region 131, and gate structure 140, which may be configured in a similar manner as described above for transistor 100 illustrated in FIGS. 1A-1C and 2A-2C. As described below, the dimensions of certain elements may be designed to achieve desired parameters, such as the gate-to-drain capacitance (Cgd) and the gate-to-source capacitance (Cgs).

As shown in FIGS. 3A-3C, the various example transistors 301, 302, and 303, may include a gate structure 140 that has a gate length 310 (for example, 0.8 µm) that is less than the portion of the cell length 317 (for example, 1.6 µm) that is attributable to the length of channel region 112 and JFET region 113. For example, as shown in FIGS. 3A-3C, gate structure 140 may have a gate length 310 that extends over channel region 112, but may be omitted from the area above JFET region 113. In other embodiments, gate structure 140 may have a gate length that extends over the entirety of channel region 112 and over a portion of JFET region 113. By scaling back the gate length, the total gate capacitance (including Cgs and Cgd) of transistors 301, 302, and 303, may be reduced as compared to embodiments such as transistor 100 in FIGS. 1A-1D and 2A-2C where gate structure 140 extends over the entirety of channel region 112 and over the entirety of JFET region 113.

The dimensions of channel region 112 may be defined at least in part by the dimensions of gate structure 140, which may provide for the accumulation of majority carriers (and thus the flow of current) in channel region 112 when a positive gate-to-source voltage is applied at the gate of the transistor. In embodiments where gate structure 140 is omitted from the area above JFET region 113, JFET region 113 may be formed with a larger JFET-area length 318 (for example, 0.6 µm) to reduce the pinch-off effect in the JFET region 113 and to ensure a conduction path may be formed from channel region 112, through JFET region 113, and through drift region 110, when a positive gate-to-source voltage is applied at the gate.

The relative widths of channel region 112 and lateral-shield region 124 relative to the cumulative cell pitch may also be designed to adjust the on-state resistance (RON) and the proportions of Cgd and Cgs relative to each other. For example, a wider channel width may decrease the contribution of the channel resistance to the overall on-state resistance (RON) of the transistor. Further, because lateral-shield region 124 may be coupled via shield-contact region 131 to the same source contact as source region 130, a larger shield width relative to the total width of channel region 112 and lateral-shield region 124 may increase the proportional Cgs value relative to Cgd. Conversely, a larger channel width relative to the total width of channel region 112 and lateral-shield region 124 may increase the proportional Cgd value relative to Cgs.

Accordingly, as illustrated by the varied dimensions of transistors 301, 302, and 303, in FIGS. 3A-3C, the channel width, shield width, and the proportions thereof, may be adjusted across varied embodiments to achieve the desired Cgs, Cgd, and RON values. For example, the cell of transistor 301 shown in FIG. 3A may have a cell width 316 of 0.6 µm, with a channel width 312 of 0.5 µm and a shield width 314 of 0.1 µm. As another example, the cell of transistor 302 shown in FIG. 3B may have a cell width 326 of 0.4 µm, with a channel width 322 of 0.3 µm and a shield width 324 of 0.1 µm. As yet another example, the cell of transistor 302 shown in FIG. 3C may have a cell width 336 of 0.4 µm, with a channel width 332 of 0.35 µm and a shield width 334 of 0.05 µm.

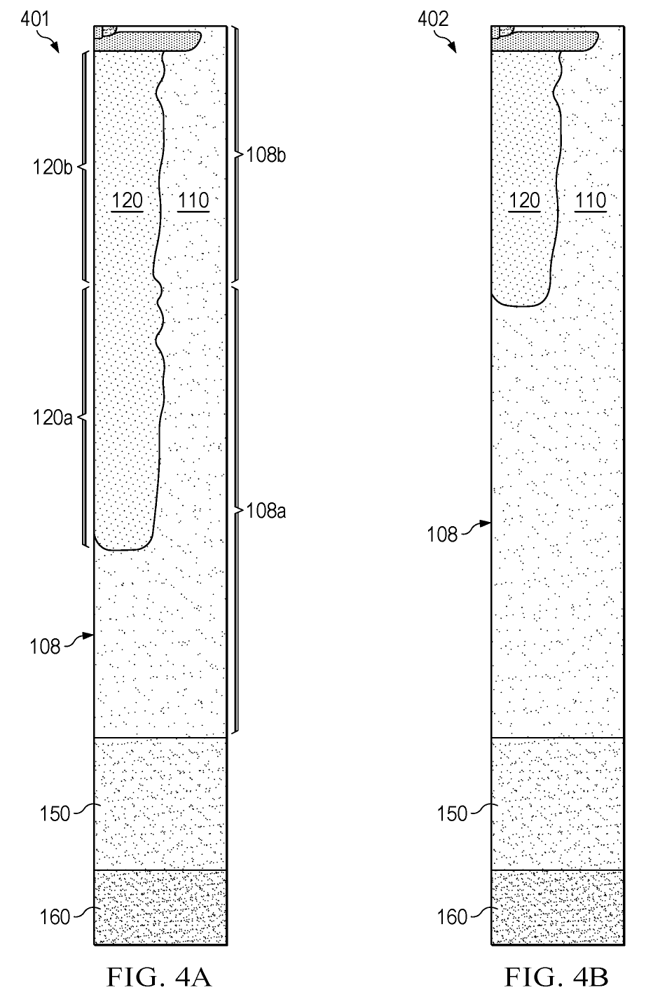

FIGS. 4A-4C illustrate side cross-sectional views of various examples of transistors in accordance with embodiments of the present disclosure. Specifically, FIGS. 4A-4C illustrate various examples that may utilize one, two, or more separate epitaxial growths to for epitaxial region 108. The transistors 401, 402, and 403 may represent various embodiments of transistor 100 described above with reference to FIGS. 1A-1C and 2A-2C.

As shown in FIG. 4A, transistor 401 may include substrate 160, buffer region 150, epitaxial region 108, as well as pillar region 120 and drift region 110 formed respectively in and by lower portions of epitaxial region 108 (lower being relative to the location of source region 130, channel region 112, and shield regions at or near the upper surface of epitaxial region 108). Similar to epitaxial region 108 of transistor 100 shown in FIG. 2A, epitaxial region 108 in transistor 401 may be formed by two epitaxial growths. For example, epitaxial region 108 may be formed by the combination of first epitaxial growth 108a and second epitaxial growth 108b. A first growth process may be used to form first epitaxial growth 108a. The first pillar-region portion 120a may then be implanted in the first epitaxial growth 108a. After first pillar-region portion 120a is implanted, a second growth process may be used to form second epitaxial growth 108b. The second pillar-region portion 120b may then be implanted in the second epitaxial growth 108b. As described above with reference to FIG. 1A, further elements of transistor 100 such as a source region, a channel region, a JFET region, a shield-contact region, a buried-shield region, and a lateral-shield region, may also be formed at or near the upper surface of epitaxial region 108 (for example, the upper surface of second epitaxial growth 108b) by further doping implants. As described below with reference to FIGS. 4B and 4C, various examples of transistors described herein may be formed with either less or more than the two epitaxial growth steps used for transistor 401.

As represented by transistor 402 shown in FIG. 4B, epitaxial region 108 may be formed by a single epitaxial growth. The pillar region 120 may then be implanted in epitaxial region 108. The depth of pillar region 120 may be limited by the achievable depth of semiconductor process doping-implant tools. Thus, the depth of pillar region 120 for transistor 402 may be less than the depth of pillar region 120 for transistor 401 that utilizes multiple stages of epitaxial growth and corresponding pillar-region implants.

As represented by transistor 403 shown in FIG. 4C, epitaxial region 108 may be formed by more than two epitaxial growths. For example, epitaxial region 108 of transistor 403 may be formed by the combination of first epitaxial growth 108a, second epitaxial growth 108b, and third epitaxial growth 108c. A first growth process may be used to form first epitaxial growth 108a. The first pillar-region portion 120a may then be implanted in the first epitaxial growth 108a. After first pillar-region portion 120a is implanted, a second growth process may be used to form second epitaxial growth 108b. The second pillar-region portion 120b may then be implanted in the second epitaxial growth 108b. After second pillar-region portion 120b is implanted, a second growth process may be used to form third epitaxial growth 108c. The third pillar-region portion 120c may then be implanted in the third epitaxial growth 108c. As described above with reference to FIG. 1A, further elements of transistor 100 such as a source region, a channel region, a JFET region, a shield-contact region, a buried-shield region, and a lateral-shield region, may also be formed at or near the upper surface of epitaxial region 108 (for example, the upper surface of third epitaxial growth 108c) by further doping implants.

The use of one, two, three, or more epitaxial growth steps to form epitaxial region 108 may be selected based on performance and cost considerations. For example, the use of more epitaxial growth steps (and corresponding pillar-region implants) may increase manufacturing costs. However, the use of more epitaxial growth steps (and corresponding pillar-region implants) may also allow for a deeper pillar region 120, and thus for a deeper super-junction area collectively formed by pillar region 120 and drift region 110. The deeper super-junction area may in turn provide for improved spread of electric fields and thus a greater breakdown voltage (BV) for a given depth of drift region 110.

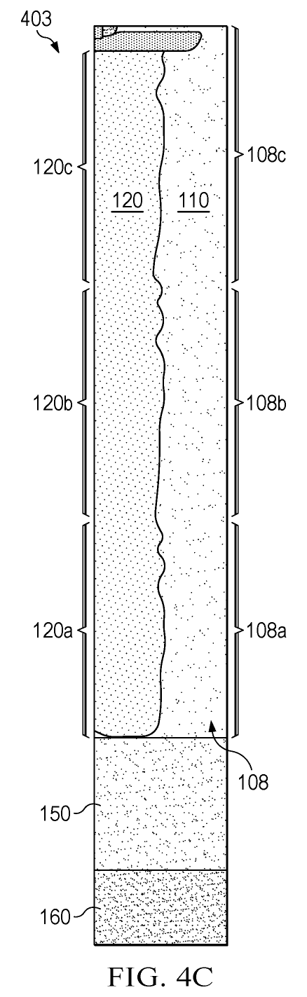

FIG. 5 illustrates a perspective cross-sectional view of transistor 500 in accordance with embodiments of the present disclosure. Specifically, FIG. 5 illustrates a perspective cross-sectional view of a portion of transistor 500 cut out from a semiconductor substrate. Although FIG. 5 illustrates multiple fingers of transistor 500, transistor 500 may include further fingers (for example, 10, 100, 1000, or more) repeated in a similar pattern in further portions of the semiconductor substrate not shown in FIG. 5. In some embodiments, transistor 500 may be a silicon carbide transistor formed on a silicon carbide (SiC) substrate. In other embodiments, transistor 500 may be implemented in silicon (Si), gallium nitride (GaN), or any other suitable semiconductor material. As described in further detail below, transistor 500 may include an accumulation-based channel region, and may thus also be referred to as an accumulation-based transistor. As also described in further detail below, transistor 500 may include a super-junction, and may thus also be referred to as a super-junction transistor.

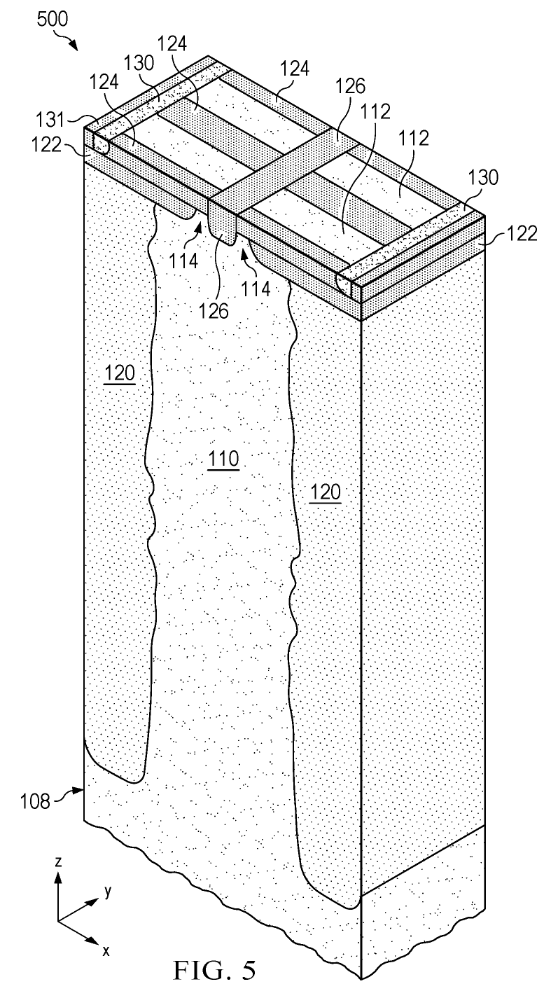

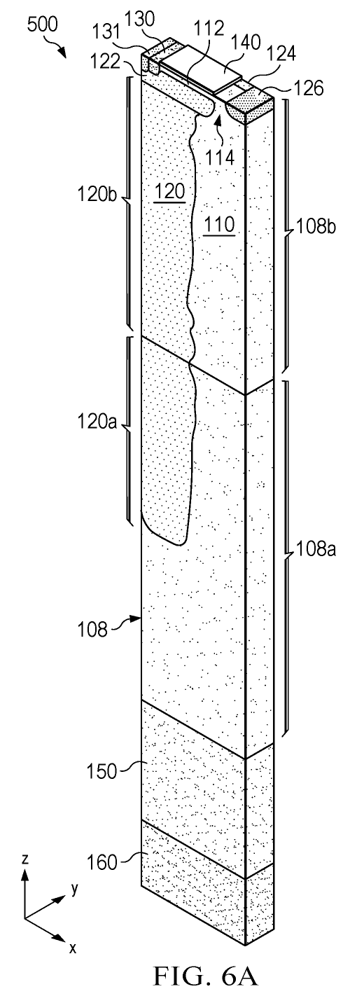

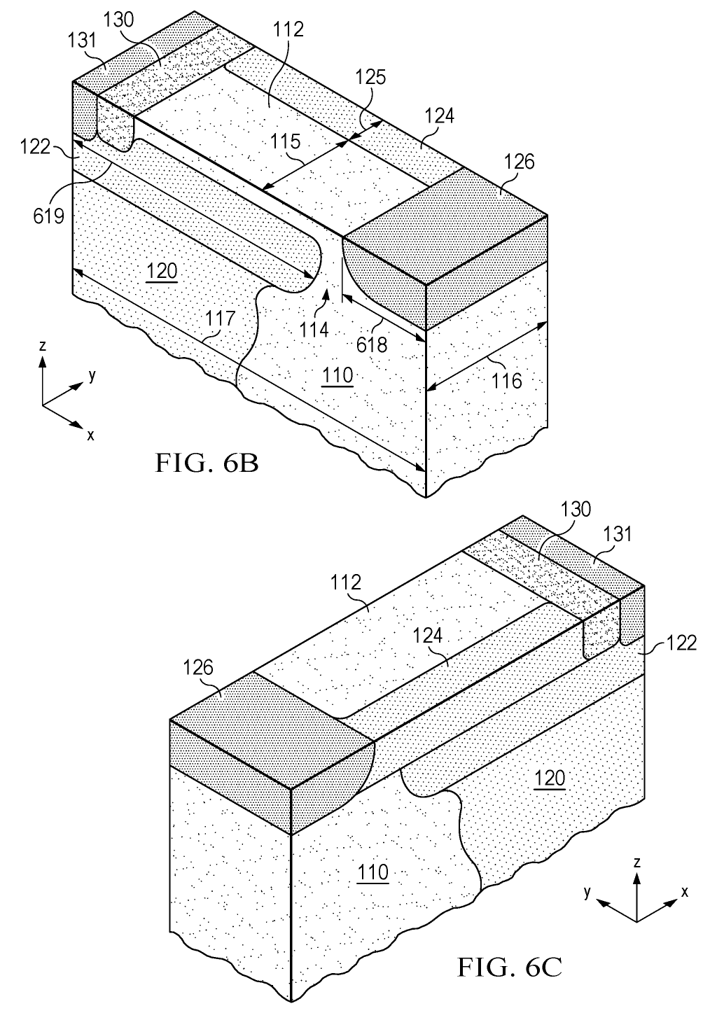

Various elements of transistor 500 may be formed in or disposed above epitaxial region 108. As described in further detail below with reference to FIG. 6A, epitaxial region 108 may be epitaxially grown on a substrate 160 that may form the drain of transistor 500. For example, epitaxial region 108 may be a silicon carbide epitaxial region formed by an epitaxial growth using a silicon carbide substrate as the seed for the epitaxial growth. Epitaxial region 108 may be initially formed with a first conductivity type. For example, in embodiments where transistor 500 is an NMOS transistor, epitaxial region 108 may be initially formed with an n-type doping that may be included, for example, during the epitaxial growth. And as described directly below with reference to FIG. 5, various elements of transistor 500 may be formed in epitaxial region 108 by further doping patterns applied to epitaxial region 108 after the epitaxial growth.

Transistor 500 may include drift region 110, channel region 112, pillar region 120, a shield region (including buried-shield region 122 and lateral-shield region 124), source region 130, and shield-contact region 131, which may be configured in a similar manner as described above for transistor 100 shown in FIGS. 1A-1C and 2A-2C. Although omitted from FIG. 5 in order to show the top-view layout of channel region 112 and lateral-shield region 124, transistor 500 may also include a gate structure 140 disposed over channel region 112 and lateral-shield region 124.

In addition, the shield region of transistor 500 may further include end-shield region 126. End-shield region 126 may be disposed at the upper surface of epitaxial region 108 and at a second end of channel region 112 that is opposite to a first end of channel region 112 that is adjacent to source region 130. End-shield region 126 may have the same second conductivity type as other portions of the shield region, including lateral-shield region 124 and buried-shield region 122. For example, in embodiments where transistor 500 is an NMOS transistor, end-shield region 126 may be formed with a p-type doping implant.

Channel region 112 may have approximately the same depth (for example, approximately 75 nm) relative to the upper surface of epitaxial region 108 as lateral-shield region 124. JFET region 114 may extend vertically from channel region 112 to drift region 110. Accordingly, channel region 112, JFET region 114, and drift region 110, may collectively form a contiguous path of the first conductivity type. For the purposes of the present disclosure, JFET region 114 may be considered to be an upper portion of drift region 110 that extends through the depth of buried-shield region 122 and end-shield region 126. For example, as shown in FIG. 5, JFET region 114 may represent an upper portion of drift region 110 that is located between a lateral end of buried-shield region 122 and end-shield region 126. Thus, as shown in the cross-section view of FIG. 5, JFET region 114 may extend vertically from channel region 112 to the lower portions of drift region 110 that are at a depth beneath the depth of buried-shield region 122 and end-shield region 126. To be clear, JFET region 114 does not represent a junction-field-effect-transistor (JFET) device separate from transistor 500, but instead represents an area within transistor 500 with a JFET-like configuration where an n-type conduction path extends through opposing p-type regions.

Although not shown in FIG. 5, shield-contact region 131 may be coupled the same source contacts that may couple source region 130 to upper metal layers that couple to a source terminal of transistor 500. And as shown in FIG. 5, end-shield region 126 may abut stripes of lateral-shield region 124. Thus, lateral-shield region 124, buried-shield region 122, and end-shield region 126, may form a contiguous area of the second conductivity type. Accordingly, shield-contact region 131, lateral-shield region 124, buried-shield region 122, and pillar region 120 may each be held at the same voltage potential as source region 130 during operation of transistor 500. Further, in embodiments that include pillar region 120, the lateral-shield region 124, buried-shield region 122, end-shield region 126, and pillar region 120 may form a contiguous area of the second conductivity type held at the same voltage potential as source region 130.

FIG. 6A illustrates a perspective cross-sectional view of transistor 500 in accordance with embodiments of the present disclosure. Specifically, FIG. 6A illustrates a zoomed out perspective cross-sectional view of a cell of transistor 500 that is repeated eight times, for example, in FIG. 5. As shown in FIG. 6A, transistor 500 may include substrate 160, buffer region 150, various features disposed in epitaxial region 108 as described above with reference to FIG. 5, and also gate structure 140. In some embodiments, gate structure 140 may extend above channel region 112.

In some embodiments, substrate 160 may be 100 µm thick for example. Substrate 160 may serve as the drain of transistor 500, and further back-side metal processing on the lower surface of substrate 160 may couple substrate 160 to the drain terminal of transistor 500. Substrate 160 may be heavily doped relative to the doping of epitaxial region 108. For example, substrate 160 may have an n-type doping concentration implemented with nitrogen at 5e18 cm⁻³ while epitaxial region 108 may have an initial n-type doping concentration implemented with nitrogen at 1e16 cm⁻³.

Epitaxial region 108 may be formed with an epitaxial growth using substrate 160 as the seed. In some embodiments, transistor 500 may optionally further include a buffer region 150 between substrate 160 and epitaxial region 108. The buffer region 150 may have the same first conductivity type as substrate 160 and epitaxial region 108 with a doping concentration greater than the doping concentration of epitaxial region 108 and lower than the doping concentration of substrate 160. For example, in embodiments as described above where substrate 160 may has an n-type doping concentration implemented with nitrogen at 5e18 cm⁻³, and epitaxial region 108 has an initial n-type doping concentration implemented with nitrogen at 1e16 cm⁻³, buffer region 150 may have an n-type doping concentration implemented with nitrogen at 1e17 cm⁻³. The medium doping concentration of buffer region 150 may help ensure that the electric field that is spread across the depth of drift region 110 does not reach the heavily doped substrate 160. In some embodiments, buffer region 150 may be considered a higher-doped portion of epitaxial region 108, and may be formed with the same epitaxial growth as epitaxial region 108 but with a higher-concentration doping.

As shown in FIG. 6A, epitaxial region 108 may be formed by the combination of first epitaxial growth 108a and second epitaxial growth 108b. In some embodiments, the depth of pillar region 120 may be limited by the achievable depth of semiconductor process doping-implant tools. Thus, in some embodiments, multiple epitaxial growth processes may be used to form epitaxial region 108. A first growth process may be used to form first epitaxial growth 108a having a depth of 5.0 µm for example. The first pillar-region portion 120a may then be implanted in the first epitaxial growth 108a. After first pillar-region portion 120a is implanted, a second growth process may be used to form second epitaxial growth 108b having a depth of 3.0 µm for example. The second pillar-region portion 120b may then be implanted in the second epitaxial growth 108b. As described above with reference to FIG. 5, further elements of transistor 500 such as source region 130, channel region 112, JFET region 114, shield-contact region 131, buried-shield region 122, lateral-shield region 124, and end-shield region 126 may also be formed at or near the upper surface of epitaxial region 108 (for example, the upper surface of second epitaxial growth 108b) by further doping implants.

FIGS. 6B and 6C illustrate perspective cross-sectional views of transistor 500 in accordance with embodiments of the present disclosure. Specifically, FIGS. 6B and 6C illustrate from different sides the upper portions of the same cell of transistor 500 that is shown in FIG. 6A. Gate structure 140 is omitted from FIGS. 6B and 6C to allow view of underlying elements.

As shown in FIG. 6B, the cell may have a cell length 117 that is greater than the sum of a buried-shield length 619 and an end-shield length 618. For example, in some embodiments, each cell of transistor 500 may have a cell length 117 equal to 1.6 µm with a buried-shield length 619 of 0.8 µm, and a end-shield length 618 of 0.3 µm. JFET region 114 may thus extend vertically from channel region 112 to drift region 110 through a gap between an end of buried-shield region 122 and end-shield region 126. Further the cell may have a cell width 116 that is equal to channel width 115 plus shield width 125. In some embodiments, the cell width 116 may be for example 0.4 µm with a channel width 115 of 0.3 µm and a shield width 125 of 0.1 µm.

As shown in FIG. 6C, buried-shield region 122 may abut lateral-shield region 124 and may extend downward from lateral-shield region 124. Further, pillar region 120 may abut buried-shield region 122 and may extend downward from buried-shield region 122. In addition, end-shield region 126 may abut an end of lateral-shield region 124. Accordingly, end-shield region 126, lateral-shield region 124, buried-shield region 122, and pillar region 120 may form a contiguous area of the second conductivity type (for example, formed with p-type doping in embodiments where transistor 500 is an NMOS transistor). Although not shown in FIGS. 6B and 6C, shield-contact region 131 may be coupled the same source contacts that may couple source region 130 to upper metal layers that couple to a source terminal of transistor 500. Accordingly, shield-contact region 131, lateral-shield region 124, end-shield region 126, buried-shield region 122, and pillar region 120 may be held at the same voltage potential as source region 130 during operation of transistor 500.

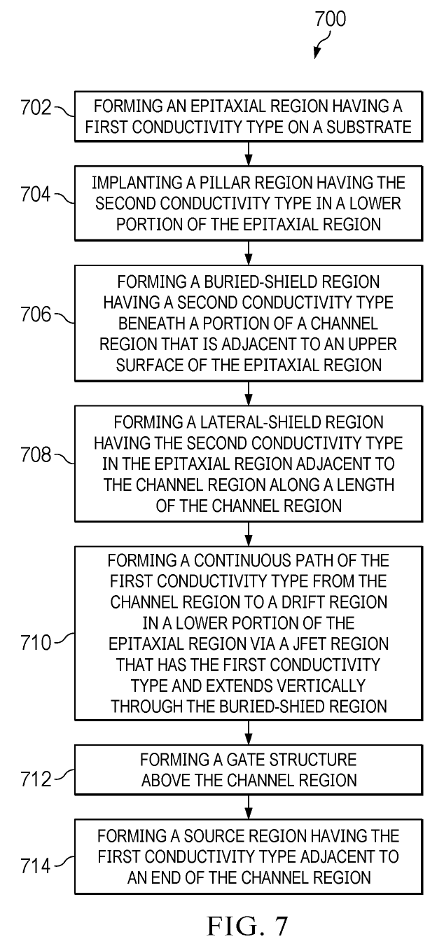

FIG. 7 illustrates method 700 for manufacturing an accumulation-based transistor in accordance with embodiments of the present disclosure. Method 700 may be performed with fewer or more steps than shown in FIG. 7. Moreover, steps of method 700 may be omitted, repeated, performed in parallel, performed in a different order than shown in FIG. 7, or performed recursively. One or more steps of method 700, although shown in an order, may be performed at the same time or in a re-ordered manner. For example, the continuous path of the first conductivity type from the channel region to the drift region described in step 710 may be formed at least in part as a result the patterning of the buried-shield region and the lateral-shield region during the formation of those respective regions in steps 706 and 708.

Although the steps illustrated in FIG. 7 generally address the formation of various layers and/or regions in a direction from the bottom of the semiconductor substrate toward the upper surface of the epitaxial region, different doping implants at different depths may be utilized in any suitable order to form the regions described herein. Further, for the sake of simplicity, additional top-side and back-side passivation, contact formation, and metal processing used to form the gate, drain, and source terminals of the transistor may be omitted from the description of method 700 below, but may be implemented in any suitable fashion including techniques known in the art.

Step 702 may include forming an epitaxial region having a first conductivity type on a substrate. For example, as described above with reference to FIGS. 1A and 2A , the epitaxial region 108 of transistor 100 may be formed by an epitaxial growth process using substrate 160 as a seed for the epitaxial growth. In embodiments where transistor 100 is an NMOS transistor, epitaxial region 108 may be grown with an initial n-type doping.

Step 704 may include implanting a pillar region having the second conductivity type in a lower portion of the epitaxial region. For example, as described above with reference to FIGS. 1A, 2A and 4A-4C, pillar region 120 may have the second conductivity type opposite of the initial first conductivity type of epitaxial region 108. For example, pillar region 120 may be formed by a p-type doping implant in the epitaxial region 108 that is initially grown with an n-type doping. The doping of epitaxial region 108 may be further tuned by an n-type doping implant. Further, pillar region 120 may be implanted in epitaxial region 108 by one or more doping implant steps corresponding to one or more epitaxial growth steps. Pillar region 120 may be formed in a lower portion of epitaxial region 108 to form a super-junction in the lower portion of epitaxial region 108 at a depth beyond a buried-shield region 122 described below with reference to step 706.

Step 706 may include forming a buried-shield region having a second conductivity type beneath a portion of a channel region that is adjacent to an upper surface of the epitaxial region. For example, as described above with reference to FIGS. 1A-1C and 2A-2C, buried-shield region 122 may be disposed by a doping implant in epitaxial region 108 under at least a portion of channel region 112, which in turn may be adjacent to an upper surface of epitaxial region 108. Further, buried-shield region 122 may have the second conductivity type. For example, in embodiments where transistor 100 is an NMOS transistor, the shield region that includes buried-shield region 122 may have a second conductivity type (formed with p-type doping) opposite of the first conductivity type (formed with n-type doping) of channel region 112.

Step 708 may include forming a lateral-shield region having the second conductivity type in the epitaxial region adjacent to the channel region along a length of the channel region. For example, as described above with reference to FIGS. 1A-1C and 2A-2C, instances of lateral-shield region 124 may be disposed by a doping implant in the epitaxial region 108 at the upper surface of epitaxial region 108 and adjacent to channel region 112 along a length of channel region 112. Further, lateral-shield region 124 may have the second conductivity type. For example, in embodiments where transistor 100 is an NMOS transistor, the shield region that includes lateral-shield region 124 may have a second conductivity type (formed with p-type doping) opposite of the first conductivity type (formed with n-type doping) of channel region 112. The doping of channel region 112 may be further tuned by an n-type doping implant.

Step 710 may include forming a continuous path of the first conductivity type from the channel region to a drift region in a lower portion of the epitaxial region via a JFET region that has the first conductivity type and extends vertically through the buried-shied region. For example, as described above with reference to FIGS. 1A-1C and 2A-2C, JFET region 113 may extend vertically from channel region 112 to drift region 110. JFET region 113 may have the same first conductivity type as channel region 112 and drift region 110. JFET region 113 may be considered to be an upper portion of drift region 110 that extends through the depth of buried-shield region 122 (as shown in FIG. 1A). For example, as shown in FIG. 1A, JFET region 113 may represent an upper portion of drift region 110 that is located between the lateral ends of two instances of buried-shield region 122. Accordingly, channel region 112, JFET region 113, and drift region 110, may collectively form a contiguous path of the first conductivity type.

Step 712 may include forming a gate structure above the channel region. For example, as described above with reference to FIGS. 1B and 2A , transistor 100 may include a gate structure 140 disposed above channel region 112 and lateral-shield region 124. Gate structure 140 may include gate dielectric 141 disposed above channel region 112 (and also above lateral-shield region 124). Gate dielectric 141 may be formed by the growth or deposition of a thin layer of silicon dioxide, silicon nitride, hafnium oxide, aluminum oxide, and/or aluminum nitride, for example. Gate structure 140 may also include polysilicon gate 142 disposed above gate dielectric 141. Polysilicon gate 142 may be formed by polysilicon deposited and patterned over gate dielectric 141. In some embodiments, polysilicon gate 142 may be doped to have the second conductivity type. For example, in embodiments where transistor 100 is an NMOS transistor, polysilicon gate 142 may be formed with a p-type doping. In other embodiments where transistor 100 is an NMOS transistor, polysilicon gate 142 may alternatively be doped with an n-type doping.

Step 714 may include forming a source region having the first conductivity type adjacent to an end of the channel region. For example, as described above with reference to FIG. 1A, source region 130 may be disposed in epitaxial region 108 adjacent to an upper surface of epitaxial region 108 and adjacent to an end of channel region 112. Source region 130 may have the first conductivity type. For example, in embodiments where transistor 100 is NMOS transistor, source region 130 may be formed with an n-type doping. In some embodiments, source region 130 may have a heavier n-type doping concentration than the initial n-type doping of epitaxial region 108.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A transistor, comprising:
an epitaxial region having a first conductivity type;
a source region having the first conductivity type and disposed in the epitaxial region at an upper surface of the epitaxial region;
a channel region having the first conductivity type and disposed along the upper surface of the epitaxial region and adjacent to the source region;
a shield region having a second conductivity type and disposed to surround a bottom side and opposing lateral sides of the channel region along at least a portion of a length of the channel region; and
a drift region formed by a lower portion of the epitaxial region and forming a contiguous path of the first conductivity type with the channel region via a JFET region extending through the shield region.

2. The transistor of claim 1, wherein the shield region includes:
a lateral-shield region and disposed in the epitaxial region adjacent to the channel region along a length of the channel region; and
a buried-shield region and disposed in the epitaxial region under at least a portion of the channel region.

3. The transistor of claim 2, wherein the lateral-shield region and the buried-shield region form a contiguous area of the second conductivity type.

4. The transistor of claim 2, further comprising a pillar region having the second conductivity type extending vertically below at least a portion of the buried-shield region.

5. The transistor of claim 4, wherein the lateral-shield region, the buried-shield region, and the pillar region form a contiguous area of the second conductivity type.

6. The transistor of claim 4, wherein the pillar region and the drift region collectively form a super-junction.

7. The transistor of claim 4, wherein alternating areas of the pillar region and the drift region extend in a direction that is orthogonal to a length direction of the channel region.

8. The transistor of claim 2, wherein the shield region further includes an end-shield region having the second conductivity type and disposed at the upper surface of the epitaxial region and at a second end of the channel region that is opposite to a first end of the channel region adjacent to the source region.

9. The transistor of claim 8, wherein the lateral-shield region, the buried-shield region, and the end-shield region form a contiguous area of the second conductivity type.

10. The transistor of claim 1, further comprising a gate structure having:
a gate dielectric disposed above the channel region; and
a polysilicon gate disposed above the gate dielectric, wherein the polysilicon gate is doped to have the second conductivity type.

11. The transistor of claim 1, further comprising a gate structure having:
a gate oxide disposed above the channel region; and
a polysilicon gate disposed above the gate oxide, wherein the polysilicon gate is doped to have the first conductivity type.

12. The transistor of claim 1, wherein:
the first conductivity type is n-type; and
the second conductivity type is p-type.

13. An accumulation-based transistor, comprising:
an epitaxial region having a first conductivity type;
a source region having the first conductivity type and disposed in the epitaxial region at an upper surface of the epitaxial region;
a channel region having the first conductivity type and disposed along the upper surface of the epitaxial region and adjacent to the source region;
a lateral-shield region having a second conductivity type and disposed in the epitaxial region adjacent to the channel region along a length of the channel region;
a buried-shield region having the second conductivity type and disposed in the epitaxial region under at least a portion of the channel region; and
a drift region formed by a lower portion of the epitaxial region extending deeper than the buried-shield region, the drift region forming a contiguous path of the first conductivity type with the channel region via a JFET region located laterally to the buried-shield region.

14. The transistor of claim 13, further comprising a pillar region having the second conductivity type extending vertically below at least a portion of the buried-shield region, wherein the pillar region and the drift region extend in a direction that is orthogonal to a length direction of the channel region and collectively form a super-junction.

15. A method of manufacturing an accumulation-based transistor, comprising:
forming an epitaxial region having a first conductivity type on a substrate;
forming a buried-shield region having a second conductivity type beneath a portion of a channel region that is adjacent to an upper surface of the epitaxial region;
forming a lateral-shield region having the second conductivity type in the epitaxial region adjacent to the channel region along a length of the channel region;
forming a continuous path of the first conductivity type from the channel region to a drift region in a lower portion of the epitaxial region via a JFET region that has the first conductivity type and extends vertically through the buried-shied region;
forming a gate structure above the channel region; and
forming a source region having the first conductivity type adjacent to an end of the channel region.

16. The method of claim 15, wherein forming the gate structure comprises:
forming a gate dielectric above the channel region; and
depositing, above the gate dielectric, a polysilicon gate that is doped to have the second conductivity type.

17. The method of claim 15, further comprising implanting a pillar region having the second conductivity type in a lower portion of the epitaxial region to form a super-junction in the lower portion of the epitaxial region at a depth beyond the buried-shield region.

18. The method of claim 17, wherein the lateral-shield region, the buried-shield region, and the pillar region form a contiguous area of the second conductivity type.

19. The method of claim 15, further comprising forming an end-shield region having the second conductivity type at a second end of the channel region that is opposite to a first end of the channel region adjacent to the source region.

20. The method of claim 19, wherein the lateral-shield region, the buried-shield region, and the end-shield region form a contiguous area of the second conductivity type.
